(19) United States
(12) Patent Application Publication
(10) Pub. No.: US 2024/0321584 A1
(43) Pub. Date: Sep. 26, 2024

(54) SELECTIVE OXIDATION PROCESSES FOR GATE-ALL-AROUND TRANSISTORS

(71) Applicant: Applied Materials, Inc., Santa Clara, CA (US)

(72) Inventors: Byeong Chan Lee, San Jose, CA (US); Benjamin Colombeau, San Jose, CA (US); Edy Cardona, Fremont, CA (US); Christopher S. Olsen, Fremont, CA (US); Shawn Thomas, Chesterfield, MO (US)

(73) Assignee: Applied Materials, Inc., Santa Clara, CA (US)

(21) Appl. No.: 18/603,360

(22) Filed: Mar. 13, 2024

Related U.S. Application Data
(60) Provisional application No. 63/453,820, filed on Mar. 22, 2023.

(51) Int. Cl. H01L 21/3065; H01L 21/02; H01L 29/66

(52) U.S. Cl. CPC H01L 21/3065; H01L 21/02057; H01L 21/02236; H01L 21/02532; H01L 29/66439

(57) ABSTRACT

Semiconductor devices, such as gate-all-around (GAA) devices, and methods of forming semiconductor devices are described. Selective oxidation processes that are useful in front-end of line (FEOL) and back-end of line (BEOL) applications and processes are also described. In FEOL processes, for example, selective oxidation protects silicon germanium (SiGe) layers during etching silicon (Si) channel recess when there is no dielectric inner spacer present. In BEOL processes, for example, selective oxidation protects growth of silicon germanium (SiGe) layers on the sidewall of a superlattice structure during bottom-up epitaxial growth.

### CROSS-REFERENCE TO RELATED APPLICATION

This application claims priority to U.S. Provisional Application No. 63/453,820, filed Mar. 22, 2023, the entire disclosure of which is hereby incorporated by reference herein.

### TECHNICAL FIELD

Embodiments of the present disclosure pertain to the field of semiconductor devices and methods and apparatus for manufacturing semiconductor devices. More particularly, embodiments of the present disclosure provide selective oxidation processes for methods of forming gate-all-around (GAA) devices.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate planar field-effect transistors (FETs) in which current flows through a semiconducting channel between a source and a drain, in response to a voltage applied to a control gate.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, the FinFET structure, and a gate-all-around (GAA) structure.

A GAA transistor includes several lattice matched nanosheet channels suspended in a stacked configuration and connected by source/drain regions. In GAA transistors with a dielectric inner spacer, the silicon (Si) channels can be etched with high selectivity relative to the dielectric inner spacer. In these cases, the dielectric inner spacer protects the silicon germanium (SiGe) in the superlattice structure. In cases where a dielectric inner spacer is not present, however, there is a need for processes in order to protect silicon germanium (SiGe) recess during the silicon (Si) channel recess.

Connecting semiconductors to a power rail is typically done on the front of the cell, which requires significant cell area. For backside power rail formation, in order to obtain a direct bottom contact to the source/drain region, without an etch stop layer and to obtain a self-aligned bottom contact structure, there is a need for improved methods for protecting silicon germanium (SiGe) growth during bottom-up SiGe growth.

### SUMMARY

One or more embodiments of the disclosure are directed to methods of forming a semiconductor device. In some embodiments, the method comprises: selectively oxidizing a superlattice structure formed on a top surface of a semiconductor substrate to form a plurality of silicon germanium oxide (SiGeO) layers, the superlattice structure comprising a plurality of first layers of a first material and a corresponding plurality of second layers of a second material alternatingly arranged in a plurality of stacked pairs, the plurality of silicon germanium oxide (SiGeO) layers forming selectively on the plurality of first layers. The method further includes laterally etching each of the plurality of second layers to form a plurality of recessed second layers; and removing the silicon germanium oxide (SiGeO) layers from each of the plurality of first layers.

Further embodiments of the disclosure are directed to methods of forming a gate-all-around (GAA) device. In some embodiments, the method comprises: selectively oxidizing a superlattice structure formed on a top surface of a semiconductor substrate to form a plurality of silicon germanium oxide (SiGeO) layers, the superlattice structure comprising a plurality of silicon germanium (SiGe) layers and a corresponding plurality of silicon (Si) layers alternatingly arranged in a plurality of stacked pairs, the plurality of silicon germanium oxide (SiGeO) layers forming selectively on the plurality of silicon germanium layers (SiGe). The method further includes laterally etching each of the plurality of silicon (Si) layers to form a plurality of recessed silicon (Si) layers; and removing the plurality of silicon germanium oxide (SiGeO) layers from each of the plurality of silicon germanium (SiGe) layers.

Additional embodiments of the disclosure are directed to a non-transitory computer readable medium including instructions, that, when executed by a controller of a processing chamber, causes the processing chamber to selectively oxidize a superlattice structure formed on a top surface of a semiconductor substrate to form a plurality of silicon germanium oxide (SiGeO) layers, the superlattice structure comprising a plurality of first layers of a first material and a corresponding plurality of second layers of a second material alternatingly arranged in a plurality of stacked pairs, the plurality of silicon germanium oxide (SiGeO) layers forming selectively on the plurality of first layers. In some embodiments, the controller causes the processing chamber to laterally etch each of the plurality of second layers to form a plurality of recessed second layers; and remove the silicon germanium oxide (SiGeO) layers from each of the plurality of first layers.

One or more embodiments of the disclosure are directed to methods of forming a semiconductor device. In some embodiments, the method comprises: recessing a source/drain region within a semiconductor substrate to form a recessed source/drain region; selectively oxidizing a superlattice structure formed on a top surface of the semiconductor substrate above the recessed source/drain region to form a plurality of silicon germanium oxide (SiGeO) layers, the superlattice structure comprising a plurality of first layers of a first material and a corresponding plurality of second layers of a second material alternatingly arranged in a plurality of stacked pairs, the plurality of silicon germanium oxide (SiGeO) layers forming selectively on the plurality of first layers; epitaxially growing a silicon germanium (SiGe) layer from a bottom of the recessed source/drain region to fill a portion of the recessed source/drain region; pre-cleaning the recessed source/drain region to remove the plurality of silicon germanium oxide (SiGeO) layers; and epitaxially growing a source/drain layer on the silicon germanium (SiGe) layer.

Further embodiments of the disclosure are directed to a method of forming a gate-all-around (GAA) device. In some embodiments, the method comprises: recessing a source/drain region within a semiconductor substrate to form a recessed source/drain region; selectively oxidizing a superlattice structure formed on a top surface of the semiconductor substrate above the recessed source/drain region to form a silicon germanium oxide (SiGeO) layer, the superlattice structure comprising a plurality of silicon germanium (SiGe) layers and a corresponding plurality of silicon (Si) layers alternatingly arranged in a plurality of stacked pairs, the silicon germanium oxide (SiGeO) layer forming selectively on the plurality of silicon germanium (SiGe) layers; epitaxially growing a silicon germanium (SiGe) layer from a bottom of the recessed source/drain region to fill a portion of the recessed source/drain region; pre-cleaning the recessed source/drain region to remove the silicon germanium oxide (SiGeO) layer; and epitaxially growing a source/drain layer on the silicon germanium (SiGe) layer.

Additional embodiments of the disclosure are directed to a non-transitory computer readable medium including instructions, that, when executed by a controller of a processing chamber, causes the processing chamber to recess a source/drain region within a semiconductor substrate to form a recessed source/drain region; selectively oxidize a superlattice structure formed on a top surface of the semiconductor substrate above the recessed source/drain region to form a silicon germanium oxide (SiGeO) layer, the superlattice structure comprising a plurality of first layers of a first material and a corresponding plurality of second layers of a second material alternatingly arranged in a plurality of stacked pairs, the silicon germanium oxide (SiGeO) layer forming selectively on the plurality of first layers; epitaxially grow a silicon germanium (SiGe) layer from a bottom of the recessed source/drain region to fill a portion of the recessed source/drain region; pre-clean the recessed source/drain region to remove the silicon germanium oxide (SiGeO) layer; and epitaxially grow a source/drain layer on the silicon germanium (SiGe) layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a process flow diagram of a method of forming a semiconductor device according to one or more embodiments;

FIG. 1B illustrates a process flow diagram of a method of forming a semiconductor device according to one or more embodiments;

FIG. 2A illustrates a cross-sectional view of a semiconductor device according to one or more embodiments;

FIG. 2B illustrates a cross-sectional view of a semiconductor device according to one or more embodiments;

FIG. 2C illustrates a cross-sectional view of a semiconductor device according to one or more embodiments;

FIG. 3A illustrates a cross-sectional view of a semiconductor device according to one or more embodiments;

FIG. 3B illustrates a cross-sectional view of a semiconductor device according to one or more embodiments;

FIG. 3C illustrates a cross-sectional view of a semiconductor device according to one or more embodiments;

FIG. 3D illustrates a cross-sectional view of a semiconductor device according to one or more embodiments;

FIG. 3E illustrates a cross-sectional view of a semiconductor device according to one or more embodiments;

FIG. 3F illustrates a cross-sectional view of a semiconductor device according to one or more embodiments; and

FIG. 4 illustrates a schematic representation of a cluster tool according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is contact between elements, and there may be intervening elements or layers. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

“Epitaxy” is a process by which a deposited film is forced into a high degree of crystallographic alignment with the substrate. Epitaxial growth is broadly defined as the condensation of gas precursors to form a film on a substrate. Liquid precursors may also be used. Vapor precursors may be obtained by chemical vapor deposition (CVD) and laser ablation. Several epitaxy techniques are now available, such as molecular beam epitaxy (MBE), epitaxial CVD, or atomic layer epitaxy (ALE).

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate. In one or ore more embodiments, the gate surrounds all of the nanosheets between the bottom substrate and above channels.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated ID. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double-or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

One or more embodiments of the disclosure are directed to methods of forming gate-all-around (GAA) devices. One or more embodiments advantageously provide methods of forming gate-all-around (GAA) devices where a dielectric inner spacer is not present.

Embodiments of the disclosure advantageously provide selective oxidation processes that are useful in front-end of line (FEOL) and back-end of line (BEOL) applications and processes.

Generally, front-end of line (FEOL) refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer.

In GAA transistors with a dielectric inner spacer, the silicon (Si) channels can be etched with high selectivity relative to the dielectric inner spacer. In these cases, the dielectric inner spacer protects the silicon germanium (SiGe) in the superlattice structure. In cases where a dielectric inner spacer is not present, however, there is a need for processes in order to protect silicon germanium (SiGe) recess during the silicon (Si) channel recess. In FEOL processes, for example, selective oxidation protects silicon germanium (SiGe) layers during the silicon (Si) channel recess.

In one or more embodiments, it has been advantageously found that the selective oxidation processes described herein help to reduce the junction resistance in the semiconductor devices.

In BEOL processes, in order to obtain a direct bottom contact to the source/drain region, without an etch stop layer and to obtain a self-aligned bottom contact structure, the selective oxidation processes described herein advantageously protects growth of silicon germanium (SiGe) layers on the sidewall of a superlattice structure during bottom-up epitaxial growth.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In the method of one or more embodiments, transistors, e.g., gate-all-around (GAA) transistors, are fabricated using a standard process flow.

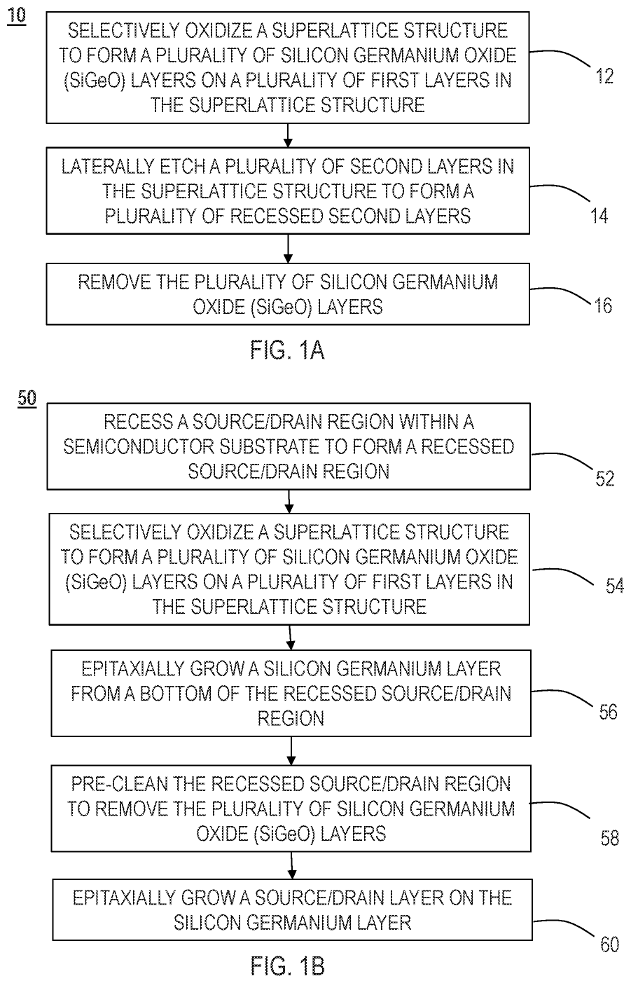

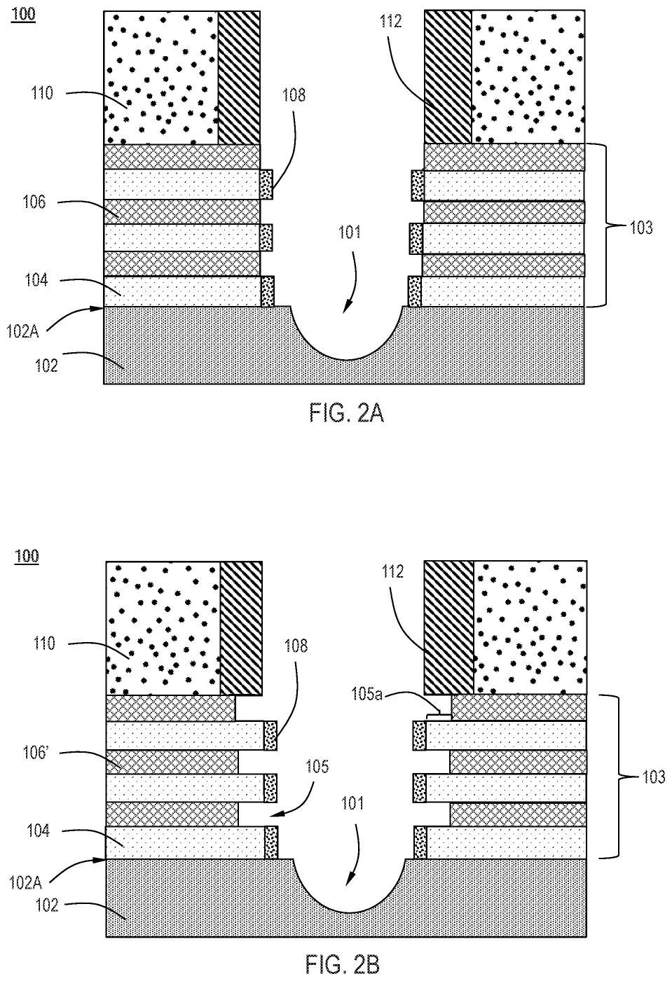

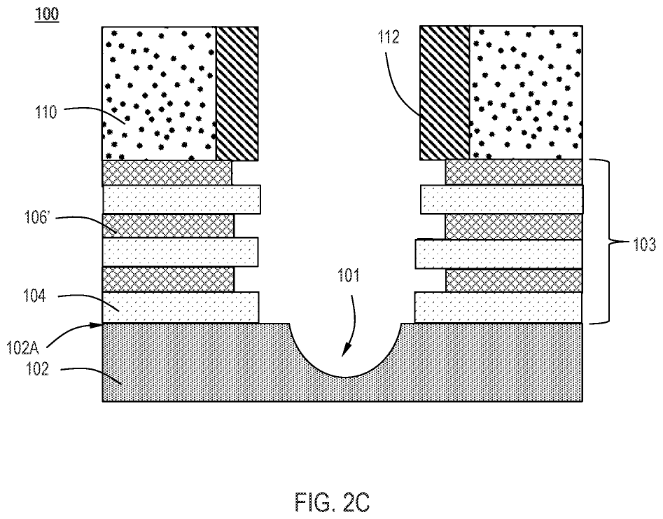

FIG. 1A illustrates a process flow diagram for method 10 for forming a semiconductor device 100 in accordance with one or more embodiments of the present disclosure. Method 10 is described below with respect to FIGS. 2A-2C, which depict the stages of fabrication of semiconductor structures, specifically gate-all-around (GAA) devices) in accordance with some embodiments of the present disclosure. The method 10 of one or more embodiments may be part of a multi-step fabrication process of a semiconductor device. Accordingly, method 10 may be performed in any suitable process chamber coupled to a cluster tool. The cluster tool may include process chambers for fabricating a semiconductor device, such as chambers configured for etching, deposition, atomic layer deposition (ALD), physical vapor deposition (PVD), chemical vapor deposition (CVD), oxidation, or any other suitable chamber used for the fabrication of a semiconductor device.

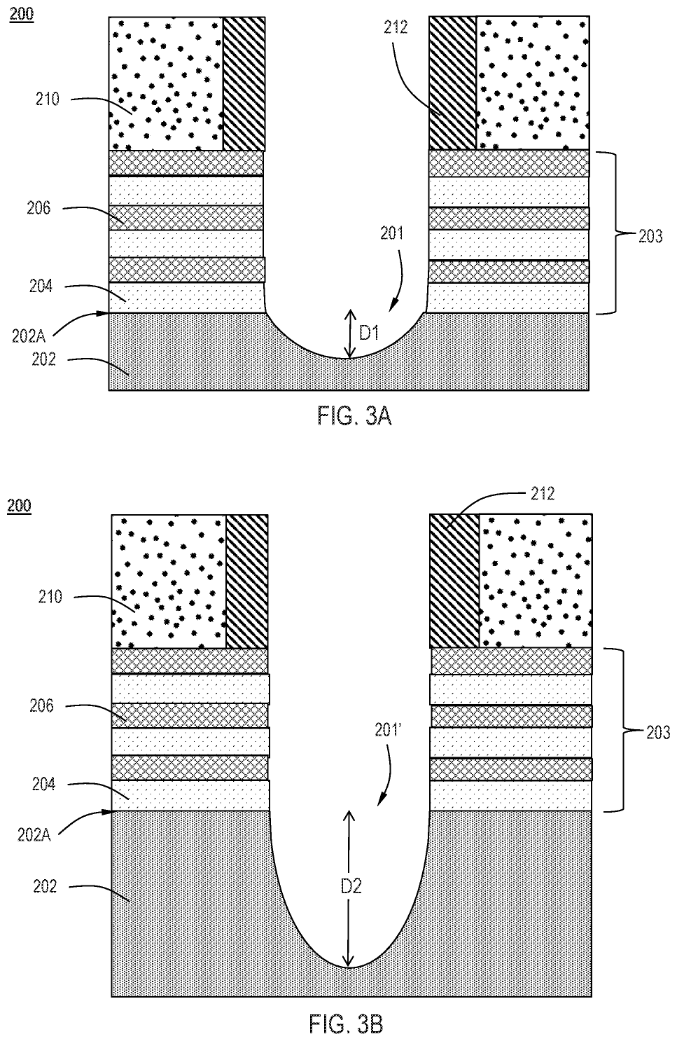

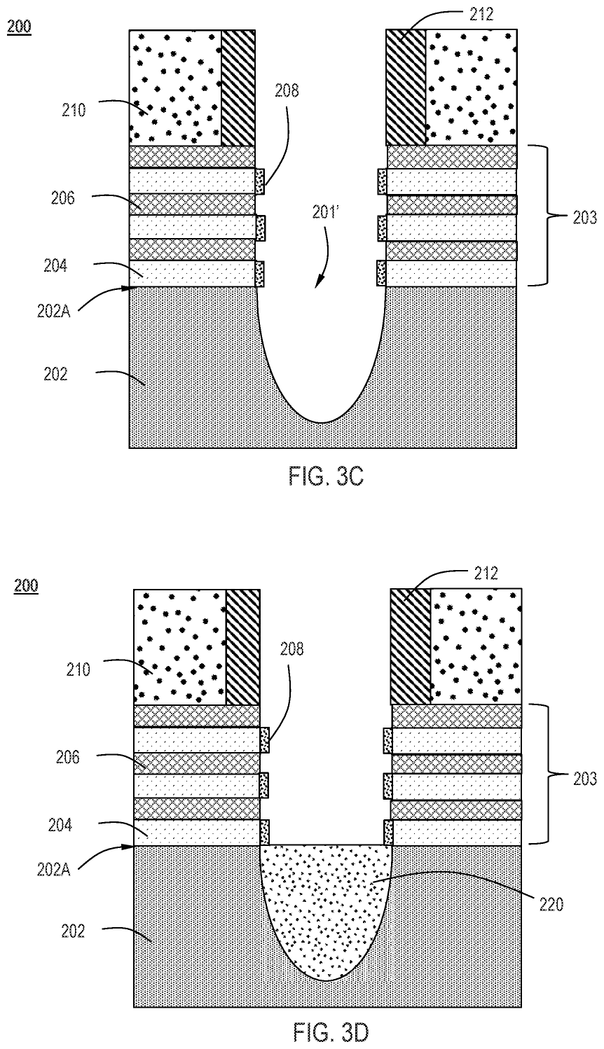

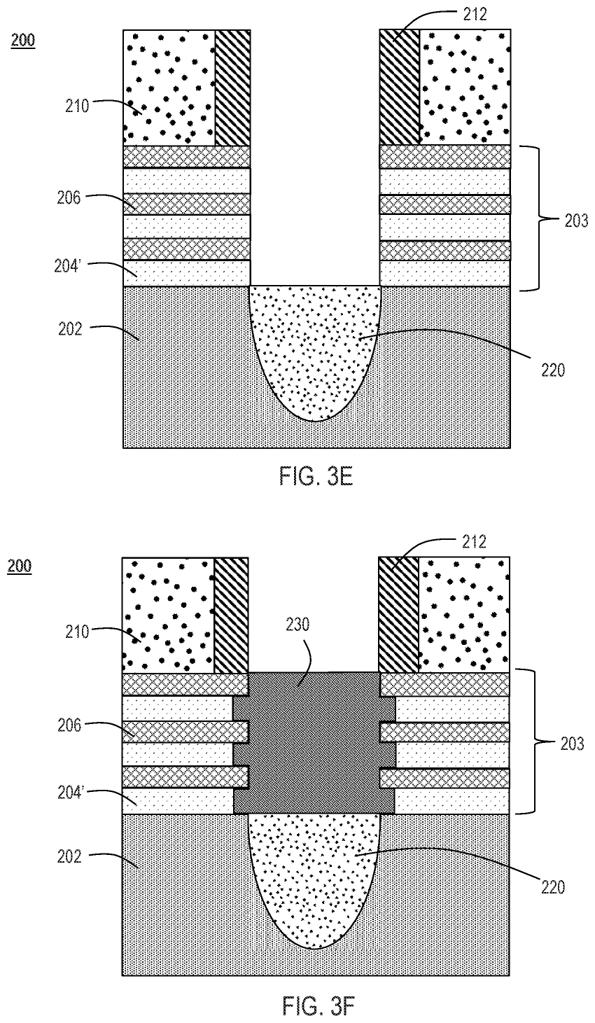

FIG. 1B illustrates a process flow diagram for method 50 for forming a semiconductor device 200 in accordance with one or more embodiments of the present disclosure. Method 50 is described below with respect to FIGS. 3A-3F, which depict the stages of fabrication of semiconductor structures, specifically gate-all-around (GAA) devices) in accordance with some embodiments of the present disclosure. The method 50 of one or more embodiments may be part of a multi-step fabrication process of a semiconductor device, specifically during backside power delivery (BPD). Accordingly, method 50 may be performed in any suitable process chamber coupled to a cluster tool. The cluster tool may include process chambers for fabricating a semiconductor device, such as chambers configured for etching, deposition, atomic layer deposition (ALD), physical vapor deposition (PVD), chemical vapor deposition (CVD), oxidation, or any other suitable chamber used for the fabrication of a semiconductor device.

Referring again to FIGS. 1A and 2A-2C, the method 10 begins at operation 12 by selectively oxidizing a superlattice structure 103 formed on a top surface 102A of a semiconductor substrate 102 to form a plurality of silicon germanium oxide (SiGeO) layers 108.

In some embodiments, the substrate 102 may be a bulk semiconductor substrate. The term bulk semiconductor substrate refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, or other suitable semiconducting materials. In some embodiments, the semiconductor material is silicon (Si). In some embodiments, the semiconductor material may be a doped material, such as n-doped silicon (n-Si), or p-doped silicon (p-Si). In some embodiments, the substrate may be doped using any suitable process such as an ion implantation process. In some embodiments, the substrate may be doped to provide a high dose of dopant at a first location of the surface of the substrate 102 in order to prevent parasitic bottom device turn on. The superlattice structure is formed atop the first location. For example, in some embodiments, the surface of the substrate may have a dopant density of about 10¹⁸ atoms/cm³ to about 10¹⁹ atoms/cm³.

In some embodiments, a source/drain region 101 is formed within the semiconductor substrate 102. The source/drain region 101 may be formed from any suitable semiconductor material, such as but not limited to silicon (Si), germanium (Ge), silicon germanium (SiGe), or the like. In some embodiments, the source/drain region 101 may be formed using any suitable deposition process, such as an epitaxial deposition process. In some embodiments, the source/drain region 101 has a depth in a range of from 30 nm to 60 nm.

At least one superlattice structure 103 is formed atop the top surface 102a of the semiconductor substrate 102. The superlattice structure 103 is formed above the source/drain region 101 formed within the semiconductor substrate 102. The superlattice structure 103 comprises a plurality of first layers 104 and a corresponding plurality of second layers 106 alternatingly arranged in a plurality of stacked pairs. In some embodiments the plurality of stacked groups of layers comprises a silicon (Si) and silicon germanium (SiGe) group.

In some embodiments, the plurality of first layers 104 comprises a first material and the corresponding plurality of second layers 106 comprises a second material. In some embodiments, the first material comprises silicon germanium (SiGe) and the second material comprises silicon (Si). In some embodiments, the first material comprises silicon (Si) and the second material comprises silicon germanium (SiGe). In some embodiments, the plurality of first layers 104 and corresponding plurality of second layers 106 can comprise any number of lattice matched material pairs suitable for forming a superlattice structure. In some embodiments, the plurality of first layers 104 and corresponding plurality of second layers 106 comprise from 2 to 50 pairs, or from 2 to 20 pairs of lattice matched materials.

Typically, a parasitic device will exist at the bottom of the superlattice structure 103. In some embodiments, implant of a dopant in the substrate, as discussed above, is used to suppress the turn on of the parasitic device. In some embodiments, the substrate 102 is etched so that the bottom portion of the superlattice structure 103 includes a substrate portion which is not removed, allowing the substrate portion to act as the bottom release layer of the superlattice structure.

The thicknesses of the first layers 104 and second layers 106 in some embodiments are in the range of about 2 nm to about 50 nm, or in the range of about 3 nm to about 20 nm. In some embodiments, the average thickness of the first layers 104 is within 0.5 to 2 times the average thickness of the second layers 106.

In some embodiments, a dielectric material (not illustrated) is deposited on the substrate 102 using conventional chemical vapor deposition (CVD) methods. In some embodiments, the dielectric material is recessed below the top surface 102A of the substrate 102 so that the bottom portion of the superlattice structure 103 is formed from the substrate 102.

In some embodiments, a replacement gate structure (e.g., a dummy gate structure 110) is formed over the superlattice structure 103. The dummy gate structure 110 defines the channel region of the transistor device. The dummy gate structure 110 may be formed using any suitable conventional deposition and patterning process known in the art.

In some embodiments, sidewall spacers 112 are formed along outer sidewalls of the dummy gate structure 110. The sidewall spacers 112 of some embodiments comprise suitable insulating materials known in the art, for example, silicon nitride (SiN), silicon oxide (SiOx), silicon oxynitride (SiON), silicon carbide (SiC), or the like. In some embodiments, the sidewall spacers 112 are formed using any suitable conventional deposition and patterning process known in the art, such as atomic layer deposition, plasma enhanced atomic layer deposition, plasma enhanced chemical vapor deposition, or low-pressure chemical vapor deposition.

In one or more embodiments, a plurality of silicon germanium oxide (SiGeO) layers 108 are advantageously formed selectively on the plurality of first layers 104. Stated differently, the plurality of silicon germanium oxide (SiGeO) layers 108 do not form on the plurality of second layers 106. In some embodiments, method 10, at operation 12, comprises selectively oxidizing the superlattice structure 103 for any suitable time period until the plurality of silicon germanium oxide (SiGeO) layers 108 are formed to a predetermined thickness.

In one or more embodiments, any selective oxidation process known to the skilled artisan may be used. In some embodiments, the selective oxidation is performed at a temperature in a range of from 300° C. to 1000° C., at a pressure in a range of from 100 T to 1000 T, and in a process gas including one or more of water (H₂O) and hydrogen (H₂).

In some embodiments, method 10, at operation 12, comprises selectively oxidizing the superlattice structure 103 for a time period in a range of from 10 seconds to 1000 seconds. In some embodiments, the selective oxidation is performed at a temperature greater than 600° C., or greater than 700° C. or greater than 800° C., or greater than 900° C. In some embodiments, each of the plurality of silicon germanium oxide (SiGeO) layers 108 has a thickness in a range of from 0.5 nm to 3.0 nm, including all values and subranges therebetween.

In some embodiments, method 10, at operation 12, comprises selectively oxidizing the superlattice structure 103 at a temperature in a range of from 400° C. to 900° C., including all values and subranges therebetween.

Referring to FIGS. 1A and 2B, the method 10, at operation 14, includes laterally etching each of the plurality of second layers 106 to form a plurality of recessed second layers 106′ having a recessed region 105 adjacent to the recessed second layers 106′ and adjacent to the source/drain region 101.

For example, where the superlattice structure 103 is composed of a plurality of second layers 106 comprising silicon (Si) and a plurality of first layers 104 comprising silicon germanium (SiGe), the plurality of second layers 106 are laterally etched to form the plurality of recessed second layers 106′. The plurality of second layers 106 may be laterally etched using any known etchant that is selective to the plurality of second layers 106, where the etchant etches the plurality of second layers 106 at a significantly higher rate than the plurality of first layers 104. In some embodiments, a selective dry etch or wet etch process may be used. In one or more embodiments, the dry etch process includes exposing the plurality of second layers 106 to common gases for etching the silicon, reactive ion etching (RIE) with a remote plasma source, ammonia (NH₃), nitrogen trifluoride (NF₃), and hydrogen (H₂). In some embodiments, the plurality of second layers 106 may be etched using a wet etchant such as, but not limited to aqueous carboxylic acid/nitric acid/HF solution and aqueous citric acid/nitric acid/HF solution.

In one or more embodiments, each of the plurality of recessed second layers 106′ has a recessed region 105 with a recessed amount 105a relative to the plurality of second layers 106 prior to etching. Stated differently, the recessed amount refers 105a to the amount of second material that is removed from the plurality of second layers 106 to form the plurality of recessed second layers 106′. In some embodiments, each of the plurality of recessed second layers 106′ has a recessed amount 105a in a range of 1 nm to 4 nm. In some embodiments, the recessed amount 105a is 3 nm.

In one or more embodiments, the lateral etching of the release layers (second material 106) leaves voids between the semiconductor material layers (first material 104). The voids between the semiconductor material layers (first material 104) can be defined by the recessed amount 105a. In some embodiments, where each of the plurality of recessed second layers 106′ has a recessed amount 105a in a range of 1 nm to 4 nm, the voids between the semiconductor material layers (first material 104) are in a range of from 1 nm to 4 nm.

Referring to FIGS. 1A and 2C, method 10, at operation 16, the silicon germanium oxide (SiGeO) layers 108 are removed from each of the plurality of first layers 104. The silicon germanium oxide (SiGeO) layers 108 may be removed by any known etching or patterning process. In some embodiments, a selective dry etch or wet etch process is used to remove the silicon germanium oxide (SiGeO) layers 108.

In some embodiments, at operation 16, removing the silicon germanium oxide (SiGeO) layers 108 from each of the plurality of first layers 104 does not affect the thickness of the plurality of first layers 104. In some embodiments, less than or equal to 1 nm of the plurality of first layers 104 is removed when removing the silicon germanium oxide (SiGeO) layers 108 at operation 16.

In one or more embodiments, without intending to be bound by theory, it is thought that selectively forming SiGeO 108 on the SiGe layers (e.g., second layers 106) advantageously protects the SiGe layers during uniform and controllable Si channel (e.g., first layer 104) lateral recess.

In one or more embodiments, a backside contact structure is provided for fabricating the backside power delivery network (BSPDN) of a gate-all-around (GAA) device. With reference to FIGS. 1B and 3A-3F, the method 50 begins at operation 52, by recessing a source/drain region 201 within a semiconductor substrate 202 to form a recessed source/drain region 201′. In some embodiments, recessing the source/drain region 201 at operation 52 increases a depth of the source/drain region 201 to form the recessed source/drain region 201′. FIG. 3A illustrates the source/drain region 201 having a depth D1, and FIG. 3B illustrates the recessed source/drain region 201′ having a depth D2 after recessing the source/drain region 201 at operation 52. In some embodiments, the depth D1 of the source/drain region 201 is in a range of from 30 nm to 60 nm. In some embodiments, the depth D2 of the recessed source/drain region 201′ is in a range of from 30 nm to 150 nm.

The recessed source/drain region 201′ has a top portion and a bottom portion. The depth D2 encompasses the entirety of the bottom portion of the recessed source/drain region 201′. The depth D2 extends from a bottom surface of the recessed source/drain region 201′ to the top surface 202A of the semiconductor substrate 202. The top portion of the recessed source/drain region 201′ extends from the top surface 202A of the semiconductor substrate 202 to a top surface of the superlattice structure. The top surface of the superlattice structure is defined by a bottom surface of the replacement gate structure (e.g., the dummy gate structure 210) and the sidewall spacers 212 that are formed along outer sidewalls of the dummy gate structure 210, which are formed over the superlattice structure. The depth of the top portion of the recessed source/drain region 201′ may be defined by the height of the superlattice structure 203. In some embodiments, the superlattice structure 203, which includes the plurality of first layers 204 and corresponding plurality of second layers 206, can comprise any number of lattice matched material pairs suitable for forming the superlattice structure. In some embodiments, the plurality of first layers 204 and corresponding plurality of second layers 206 comprise from 2 to 50 pairs of lattice matched materials, or from 2 to 10 pairs of lattice matched pairs. Stated differently, the depth of the top portion of the recessed source/drain region 201′ may be defined by the total thickness of 2 to 50 pairs, or from 2 to 10 pairs of lattice matched materials.

Referring to FIGS. 1B and 3C, at operation 54 of method 50, advantageously, the superlattice structure 203 formed on the top surface 202A of the semiconductor substrate 202 above the recessed source/drain region 201′ is selectively oxidized to form a plurality of silicon germanium oxide (SiGeO) layers 208. In one or more embodiments, the plurality of silicon germanium oxide (SiGeO) layers 208 are selectively formed on the plurality of first layers 204. The selective oxidation process of operation 54 may include the same process as operation 12 of method 10, shown in FIGS. 1A and 2A and as described above.

Referring to FIGS. 1B and 3D, at operation 56 of method 10, a silicon germanium (SiGe) layer 220 is epitaxially grown from a bottom of the recessed source/drain region 201′ to fill a portion of the recessed source/drain region 201′. The epitaxial growth process of operation 56 may include any suitable epitaxial growth process or deposition process known to the skilled artisan, such as those described herein.

In some embodiments, the silicon germanium (SiGe) layer 220 has any suitable thickness. In some embodiments, the silicon germanium (SiGe) layer 220 fills some of the bottom portion of the recessed source/drain region 201′. In some embodiments, the silicon germanium (SiGe) layer 220 fills the entirety of the bottom portion of the recessed source/drain region 201′. Stated differently, in some embodiments, the silicon germanium (SiGe) layer 220 fills the depth D2, which extends from the bottom surface of the recessed source/drain region 201′ to the top surface 202A of the semiconductor substrate 202. In embodiments where the silicon germanium (SiGe) layer 220 fills the entire depth D2, which extends from the bottom surface of the recessed source/drain region 201′ to the top surface 202A of the semiconductor substrate 202, the silicon germanium (SiGe) layer 220 has a depth in a range of from 30 nm to 150 nm.

Referring to FIGS. 1B and 3E, method 50 includes, at operation 58, pre-cleaning the recessed source/drain region 201′ to remove the plurality of silicon germanium oxide (SiGeO) layers 208.

The pre-cleaning process of operation 58 may include any suitable etching process known to the skilled artisan. In one or more embodiments, the pre-cleaning process of operation 58 may include the same process as operation 16 of method 10, shown in FIGS. 1A and 2C and described above. In some embodiments, removing the silicon germanium oxide (SiGeO) layers 208 from each of the plurality of first layers 204 does not affect the thickness of the plurality of first layers 204.

Referring to FIGS. 1B and 3F, the method 50 comprises, at operation 60, epitaxially growing a source/drain layer 230 on the silicon germanium (SiGe) layer 230. The epitaxial growth process of operation 60 may include any suitable deposition process, such as those described herein.

In some embodiments, the source/drain layer 230 has any suitable thickness. In some embodiments, the source/drain layer 230 fills some of the top portion of the recessed source/drain region 201′. In some embodiments, the source/drain layer 230 fills the entirety of the top portion of the recessed source/drain region 201′. Stated differently, in some embodiments, the source/drain layer 230 fills the depth of the top portion of the recessed source/drain region 201′, which may be defined by the height of the superlattice structure 203 (the total thickness of 2 to 50 pairs, or from 2 to 10 pairs of lattice matched materials).

In one or more embodiments, without intending to be bound by theory, it is thought that selectively forming SiGeO layers 208 on the SiGe layers (e.g., second layer 206), helps to protect SiGe growth on the sidewall of the superlattice structure 203 during bottom up SiGe growth while fabricating the backside power delivery network (BSPDN).

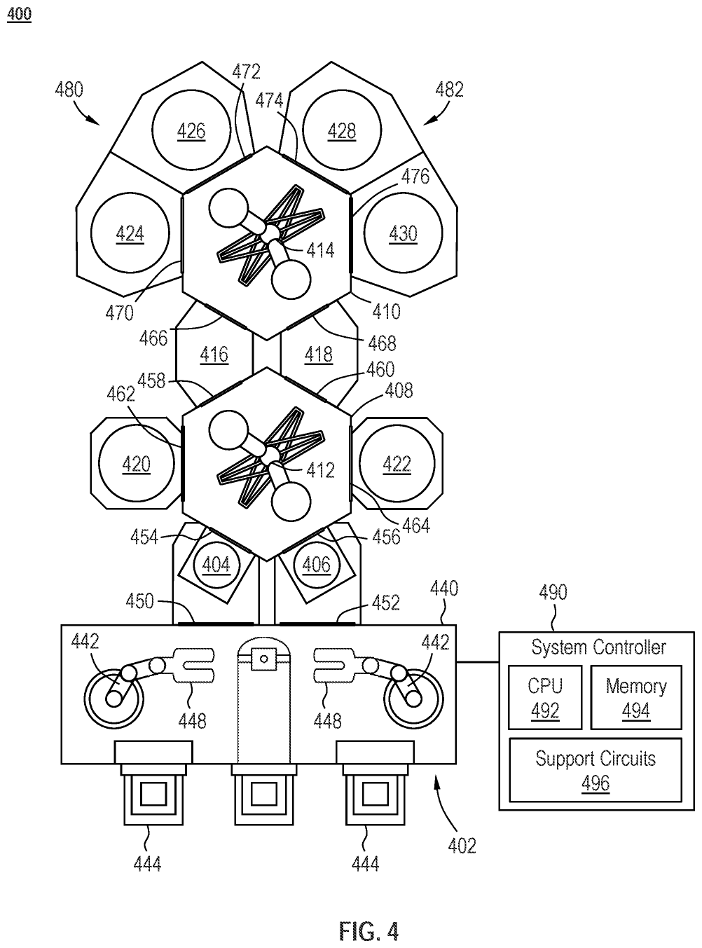

Some embodiments of the disclosure are directed to integrated processes which are performed within a single cluster tool. FIG. 4 is a schematic top-view diagram of an example multi-chamber processing system 400 according to one or more embodiments. FIG. 4 illustrates a schematic top-view diagram of an example of a multi-chamber processing system 400 according to embodiments of the present disclosure. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the processing system 400 can be processed in and transferred between the various chambers without exposing the wafers to an ambient environment exterior to the processing system 400 (e.g., an atmospheric ambient environment such as may be present in a fab). For example, the wafers can be processed in and transferred between the various chambers in a low pressure (e.g., less than or equal to about 40 to 80 Torr) or vacuum environment without breaking the low pressure or vacuum environment between various processes performed on the wafers in the processing system 400. Accordingly, the processing system 400 may provide an integrated solution for some processing of wafers.

In the illustrated example of FIG. 4, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

One or more embodiments provide a non-transitory computer readable medium (e.g., memory 494) including instructions, that, when executed by a controller (e.g., controller 490) of a processing chamber (or a multi-chamber processing system 400), causes the processing chamber to perform the operations of method 10. Further embodiments provide a non-transitory computer readable medium (e.g., memory 494) including instructions, that, when executed by a controller (e.g., controller 490) of a processing chamber (or a multi-chamber processing system 400), causes the processing chamber (or the multi-chamber processing system 400) to perform the operations of method 50.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
selectively oxidizing a superlattice structure formed on a top surface of a semiconductor substrate to form a plurality of silicon germanium oxide (SiGeO) layers, the superlattice structure comprising a plurality of first layers of a first material and a corresponding plurality of second layers of a second material alternatingly arranged in a plurality of stacked pairs, the plurality of silicon germanium oxide (SiGeO) layers forming selectively on the plurality of first layers;
laterally etching each of the plurality of second layers to form a plurality of recessed second layers; and
removing the silicon germanium oxide (SiGeO) layers from each of the plurality of first layers.

2. The method of claim 1, wherein the first material comprises silicon germanium (SiGe) and the second material comprises silicon (Si).

3. The method of claim 1, wherein the first material comprises silicon (Si) and the second material comprises silicon germanium (SiGe).

4. The method of claim 1, wherein each of the plurality of recessed second layers has a recessed amount in a range of 1 nm to 4 nm.

5. The method of claim 4, wherein the recessed amount is 3 nm.

6. The method of claim 1, wherein each of the plurality of silicon germanium oxide (SiGeO) layers has a thickness in a range of from 0.5 nm to 3.0 nm.

7. The method of claim 1, comprising selectively oxidizing the superlattice structure at a temperature in a range of from 400° C. to 900° C.

8. The method of claim 1, wherein less than or equal to 1 nm of the plurality of first layers is removed when removing the silicon germanium oxide (SiGeO) layers.

9. The method of claim 1, wherein the semiconductor device is a gate-all-around (GAA) device.

10. A method of forming a semiconductor device, the method comprising:
recessing a source/drain region within a semiconductor substrate to form a recessed source/drain region;
selectively oxidizing a superlattice structure formed on a top surface of the semiconductor substrate above the recessed source/drain region to form a plurality of silicon germanium oxide (SiGeO) layers, the superlattice structure comprising a plurality of first layers of a first material and a corresponding plurality of second layers of a second material alternatingly arranged in a plurality of stacked pairs, the plurality of silicon germanium oxide (SiGeO) layers forming selectively on the plurality of first layers;
epitaxially growing a silicon germanium (SiGe) layer from a bottom of the recessed source/drain region to fill a portion of the recessed source/drain region;
pre-cleaning the recessed source/drain region to remove the plurality of silicon germanium oxide (SiGeO) layers; and
epitaxially growing a source/drain layer on the silicon germanium (SiGe) layer.

11. The method of claim 10, wherein the source/drain region has a depth in a range of from 30 nm to 60 nm and the recessed source/drain region has a depth in a range of from 30 nm to 150 nm.

12. The method of claim 10, wherein the first material comprises silicon germanium (SiGe) and the second material comprises silicon (Si).

13. The method of claim 10, wherein the first material comprises silicon (Si) and the second material comprises silicon germanium (SiGe).

14. The method of claim 10, wherein each of the plurality of silicon germanium oxide (SiGeO) layers has a thickness in a range of from 0.5 nm to 3.0 nm.

15. The method of claim 10, comprising selectively oxidizing the superlattice structure at a temperature in a range of from 400° C. to 900° C.

16. The method of claim 10, wherein the source/drain layer comprises one or more of silicon (Si), germanium (Ge), silicon germanium (SiGe), or a group III/V compound semiconductor.

17. The method of claim 10, wherein the semiconductor device is a gate-all-around (GAA) device.

18. A non-transitory computer readable medium including instructions, that, when executed by a controller of a processing chamber, causes the processing chamber to form a semiconductor device by:
recessing a source/drain region within a semiconductor substrate to form a recessed source/drain region;
selectively oxidizing a superlattice structure formed on a top surface of the semiconductor substrate above the recessed source/drain region to form a silicon germanium oxide (SiGeO) layer, the superlattice structure comprising a plurality of silicon germanium (SiGe) layers of and a corresponding plurality of silicon (Si) layers alternatingly arranged in a plurality of stacked pairs, the silicon germanium oxide (SiGeO) layer forming selectively on the plurality of silicon germanium (SiGe) layers;
epitaxially growing a silicon germanium (SiGe) layer from a bottom of the recessed source/drain region to fill a portion of the recessed source/drain region;
pre-cleaning the recessed source/drain region to remove the silicon germanium oxide (SiGeO) layer; and
epitaxially growing a source/drain layer on the silicon germanium (SiGe) layer.

19. The non-transitory computer readable medium of claim 18, wherein each of the plurality of silicon germanium oxide (SiGeO) layers has a thickness in a range of from 0.5 nm to 3.0 nm.

20. The non-transitory computer readable medium of claim 18, wherein the source/drain layer comprises one or more of silicon (Si), germanium (Ge), silicon germanium (SiGe), or a group III/V compound semiconductor.
